(19) United States
(12) Patent Application Publication
(10) Pub. No.: US 2006/0237750 A1
(43) Pub. Date: Oct. 26, 2006

(54) Field effect transistor structures

(76) Inventors: James Oakes, Sudbury, MA (US); Vincent Pelliccia, Londonderry, NH (US)

Correspondence Address: James S. Finn, 14431 Goliad Dr., Box #8, Malakoff, TX, 75148, US

(21) Appl. No.: 11/455,333

(22) Filed: Jun. 19, 2006

Related U.S. Application Data
(62) Division of application No. 10/873,510, filed on Jun. 21, 2004.

(51) Int. Cl. H01L 29/76

(52) U.S. Cl. 257/213

(57) ABSTRACT

An embodiment of the present invention provides a structure comprising a field effect transistor (FET) comprising: at least one source rail with at least one source finger; at least one drain rail with at least one drain finger; and at least one serpentine gate having a plurality of gate fingers, said serpentine gate serpentining between said at least one source finger and said at least one drain finger; and at least one feedforward capacitor symmetrically coupled with said FET via at least one gate rail.

### BACKGROUND OF THE INVENTION

Field effect transistor (FET) structures are transistors with electric field controlling output: a transistor, with three or more electrodes, in which the output current is controlled by a variable electric field. Conventional FET structures use serpentine gates and feed forward capacitors to couple RF energy into the gate network. They benefit from this coupled energy, limited by the gate resistance of the serpentine gate.

One example of such a conventional FET structure is described in U.S. Pat. No. 6,426,525. The '525 patent sets forth a FET structure which includes a FET including a gate having a plurality of gate fingers, a plurality of source fingers, and a plurality of drain fingers; and a feedforward capacitor electrically coupled with the FET for evenly or symmetrically distributing capacitance of the feedforward capacitor to the gate fingers and reducing the effect of distributed resistance along the gate.

However, one shortcoming with existing FET structures, such as that described in the '525 patent is the non-uniformity of the distribution of RF energy into the gate network. Thus, there is a strong need for FET structures with improved performance such as uniform RF distribution.

### SUMMARY OF THE INVENTION

The present invention provides a structure comprising a field effect transistor (FET) comprising at least one source rail with at least one source finger, at least one drain rail with at least one drain finger, and at least one serpentine gate having a plurality of gate fingers, the serpentine gate serpentining between the at least one source finger and the at least one drain finger; and at least one feedforward capacitor asymmetrically coupled with the FET via at least one gate rail. Further, the serpentine gate may include first and second ends that are open at one end or closed at one end and the serpentine gate may include first and second ends that are connected to the at least one gate rail. The structure of one embodiment of the present invention may further include the FET being serially connected with at least one additional FET.

Another embodiment of the present invention provides a structure comprising a first field effect transistor (FET) comprising: at least one source rail with at least one source finger; at least one drain rail with at least one drain finger; and at least one serpentine gate having a plurality of gate fingers, the serpentine gate serpentining between the at least one source finger and the at least one drain finger; and at least one feedforward capacitor asymmetrically coupled with the first FET; a second field effect transistor (FET) comprising: at least one source rail with at least one source finger; at least one drain rail with at least one drain finger; and at least one serpentine gate having a plurality of gate fingers, the serpentine gate serpentining between the at least one source finger and the at least one drain finger; and the at least one feedforward capacitor asymmetrically, even symmetrically or odd symmetrically coupled with the second FET, the second FET coupled to the first FET. Further, this embodiment may provide at least one additional FET, the at least one additional FET comprising: at least one source rail with at least one source finger; at least one drain rail with at least one drain finger; and at least one serpentine gate having a plurality of gate fingers, the serpentine gate serpentining between the at least one source finger and the at least one drain finger; and the at least one feedforward capacitor asymmetrically, even symmetrically or odd symmetrically coupled with the at least one additional FET, the at least one additional FET coupled to the second FET and/or to the first FET.

In yet another embodiment of the present invention is provided a method of coupling RF energy into a gate network, comprising asymmetrically coupling a field effect transistor (FET) with a feedforward capacitor via a gate rail. The FET of this method may include at least one gate having a plurality of serpentine gate fingers; at least one source rail with at least one source finger; and at least one drain rail with at least one drain finger, wherein the serpentine gate fingers are serpentining between the at least one source finger and the at least one drain finger with at least one serpentine gate.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 illustrates an embodiment of the present invention which uses a gate rail and asymmetric feed of a feedforward capacitor;

FIG. 2 illustrates an embodiment of the present invention which uses a gate rail and asymmetric feed of a feedforward capacitor with series connected FETs;

FIG. 3 is another illustration of an embodiment of the present invention which uses a gate rail and asymmetric feed of a feed forward capacitor with series connected FETs;

FIG. 4 illustrates an embodiment of the present invention which uses a gate rail and even symmetric feed of a feed forward capacitor;

FIG. 5 illustrates an embodiment of the present invention which uses a gate rail with a discrete feedforward capacitor and asymmetric feed of a feedforward capacitor;

FIG. 6 illustrates an embodiment of the present invention which uses a gate rail with a discrete feedforward capacitor and asymmetric feed of the feedforward capacitor;

FIG. 7 illustrates an embodiment of the present invention which uses a gate rail and odd symmetric feed of a feed forward capacitor;

FIG. 8 illustrates an embodiment of the present invention which uses a gate rail and asymmetric feed of a feed forward capacitor and open gate ends;

FIG. 9 illustrates an embodiment of the present invention which uses a gate rail and even symmetric feed of a feed forward capacitor and open gate ends;

FIG. 10 illustrates an embodiment of the present invention which uses an array of parallel connected FETs and asymmetrical feed of feedforward capacitors; and

FIG. 11 illustrates an embodiment of the present invention which uses distributed feedforward capacitors integrated into a source and drain fingers.

### DETAILED DESCRIPTION

Traditionally FET structures may have used serpentine gates and feed forward capacitors to couple RF energy into a gate network. They benefit from this coupled energy may be limited by the gate resistance of the serpentine gate. However, in an embodiment of the present invention a gate rail may be used to lower the resistance and uniformly distribute the RF energy into the gate network. By uniformly distributing the RF energy, harmonic signal distortion can be reduced. As will be described in more detail below, in an embodiment of the present invention, the coupled energy may be directed into the gate by a feedforward capacitor using an asymmetric feed, a symmetric feed or an odd symmetric feed and the feedforward capacitor may be discrete or it may be integrated into the source or drain rails.

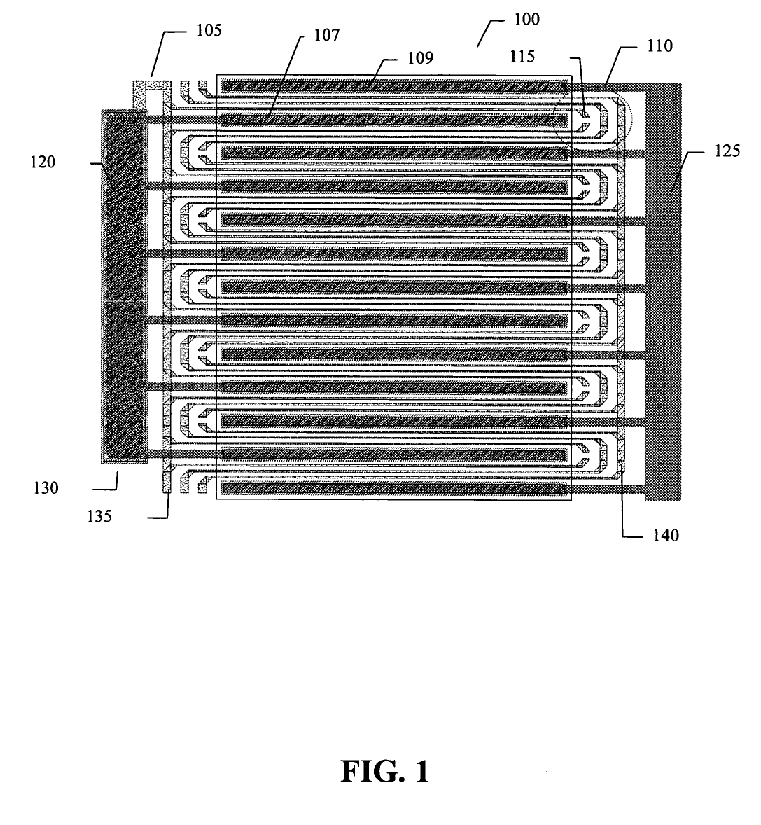

Turning now to FIG. 1, shown generally at 100, is an embodiment of the present invention which uses gate rails 135 and 140 and asymmetric feed 105 of a feed forward capacitor 120. The RF energy is AC coupled into the feedforward capacitor 120 and then asymmetrically coupled 105 into the gate rails 135 and 140 allowing uniform distribution into the FETs gate.

Thus, the embodiment of FIG. 1 provides a structure comprising a field effect transistor (FET) comprising at least one gate 110 (although in this embodiment six gates are depicted, it is understood that one or more gates can be utilized without falling outside the scope of the present invention) having a plurality of gate fingers (one of such fingers is depicted at 115, although it is understood the gate 110 may comprise any number of fingers). The FET further comprises at least one source rail 130 with at least one source finger 107 and at least one drain rail 125 with at least one drain finger 109; and at least one feedforward capacitor 120 asymmetrically coupled 105 with the FET via at least one gate rail 135 and/or 140. In one embodiment of the present invention, as depicted in FIG. 1, the feed forward capacitor may be integrated into source rail 130 or drain rail 125. Although the present invention is not limited in this respect.

An embodiment of the present invention provides that the at least one gate 110 may be at least one serpentine gate serpentining between the at least one source finger 107 and the at least one drain finger 109 and further the serpentine gate may include first and second ends that are connected to the at least one gate rail. The ends of the gate may be either connected or left open as shown at 115 of FIG. 1. Whether or not to leave the ends open, such as at 115, depends on the performance parameters and ease of manufacture desired. The serpentine gate may include first and second ends that may be connected to the at least one feedforward capacitor 120 via the at least one gate rail 135.

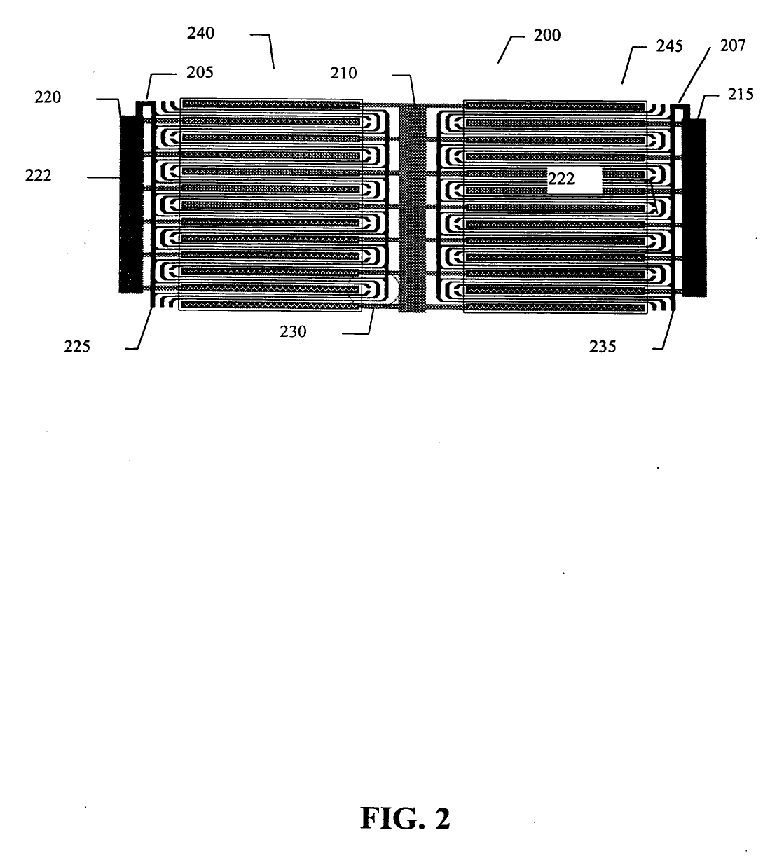

Turning now to FIG. 2, at 200 is generally shown a FET 240 that may be serially connected with at least one additional FET 245. The at least one additional FET 245 may be connected at one end 210 of the FET 240, and more specifically in an embodiment of the present invention may be connected to the FET 240 by any combination of the source 220 and/or the drain 210 rails. By providing the FET 245 being serially connected with the at least one additional FET 245 enables an even symmetric feed 205 and 207 of the at least one feedforward capacitor 222. The embodiment of FIG. 2 may include gate 230 of FET 240 and gate 235 of FET 245.

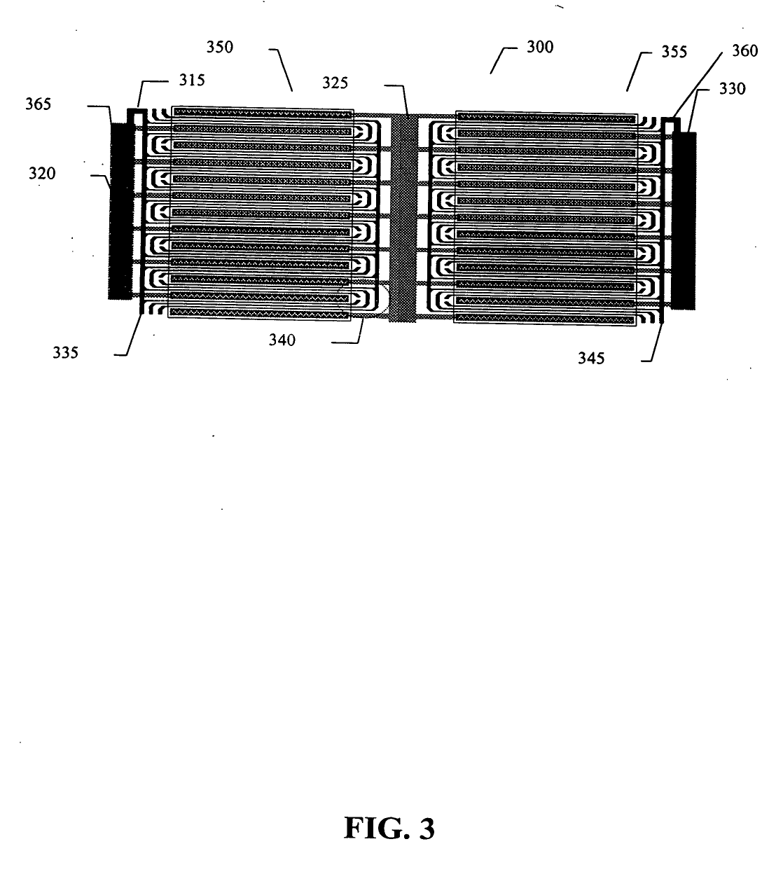

Turning now to FIG. 3 is an illustration of an embodiment of the present invention which uses at least one gate rail 335 and 345 and asymmetric feed 315 of a feed forward capacitor 320 with series connected FETs 350 and 355. Symmetrical feed may be provided by FET 355 providing feed 360. As with the embodiment of FIG. 2 the FETs 350 and 355 may be combined at source rail 365 or drain rail 325. Gates for FET 350 are depicted at 340 and for FET 355 at 345.

As with the embodiment of FIG. 2 the embodiment of FIG. 3 may provide that the at least one gate 340 and 345 is at least one serpentine gate serpentining between the at least one source finger and the at least one drain finger.

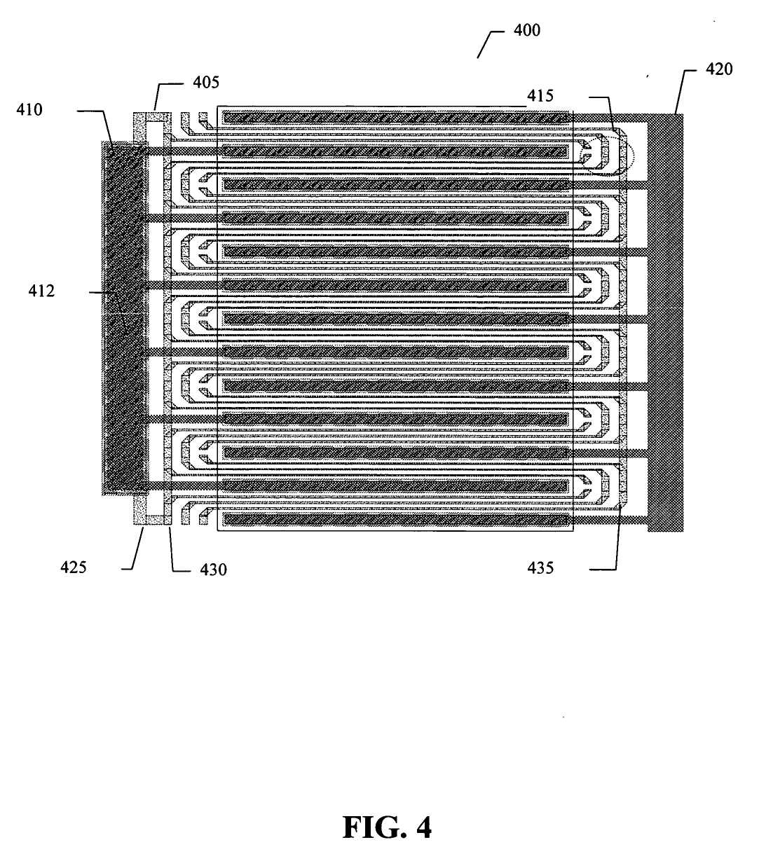

Turning now to FIG. 4, shown generally at 400, is an illustration of an embodiment of the present invention which uses at least one gate rail 430 and 435 and even symmetric feed 405 and 425 of a feed forward capacitor 412. In this embodiment the feed forward capacitor 412 is integrated into source rail 410. The structure of FIG. 4 may be similar the embodiment of FIG. 1 with the addition of additional feed 425. Thus, it may comprise a field effect transistor (FET) comprising at least one gate 415 having a plurality of gate fingers; at least one source rail 410 that may have at least one source finger; and at least one drain rail 420 that may have at least one drain finger; and at least one feedforward capacitor 412 symmetrically coupled 405 and 425 with the FET via at least one gate rail 430 and 435.

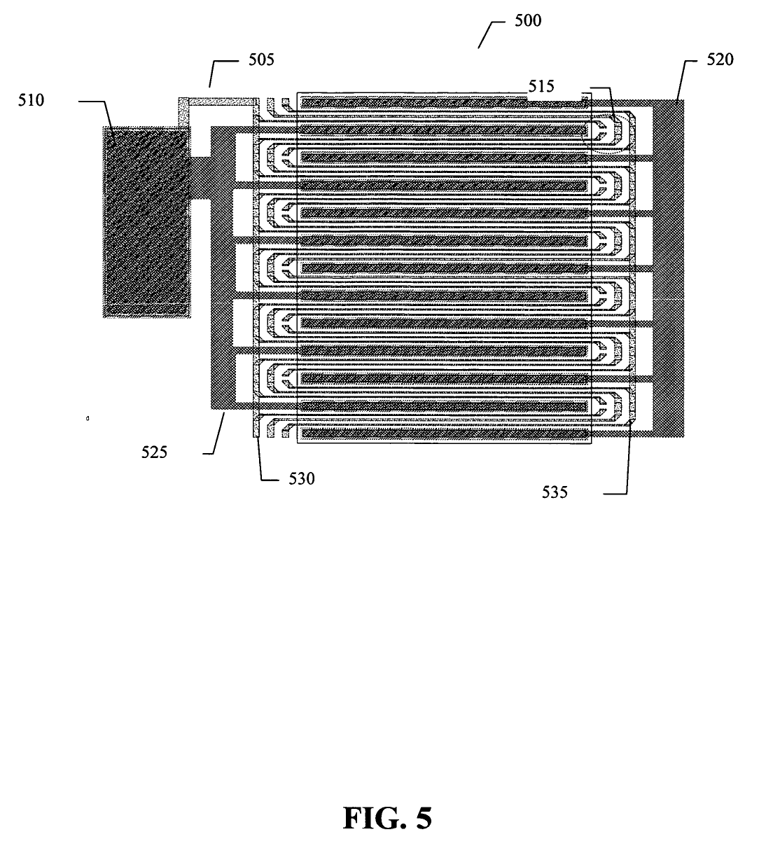

As can be seen, although the aforementioned embodiments have integrated feed forward capacitors with the source or drain rails, a discreet capacitor can be used in an embodiment of the present invention. Thus, in FIG. 5 is shown generally as 500 an illustration of an embodiment of the present invention which uses a gate rail 530 and 535 with a discrete feedforward capacitor 510 and asymmetric feed 505 of a feedforward capacitor 510. As feedforward capacitor 510 is discreet, neither source rail 525 nor drain rail 520 is integrated with feedforward capacitor 510. Gates are shown at 515, and again, can be open at either end or closed.

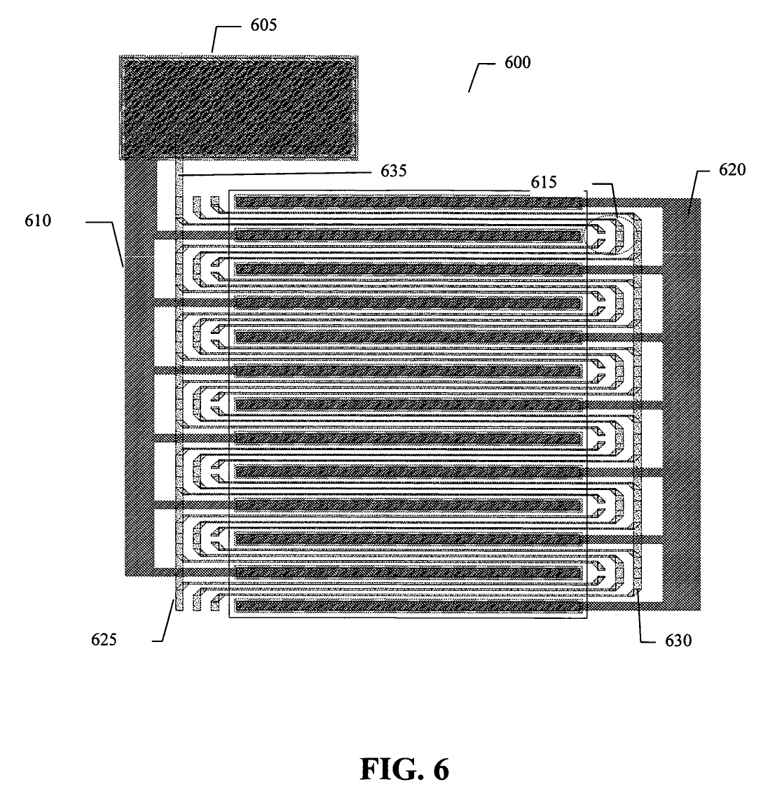

Turning now to FIG. 6, at 600 generally illustrates an embodiment of the present invention which uses at least one gate rail 625 and 630 with a discrete feedforward capacitor 605 and asymmetric feed 635 of the feedforward capacitor 605. FIG. 6 illustrates the ability to place discrete feedforward capacitor 605 in any number of positions and reiterates the fact that feedforward capacitor 605 need not be integrated with source or drain rails 610 and 620. Gates are shown at 615, and again, can be open at either end or closed in this embodiment.

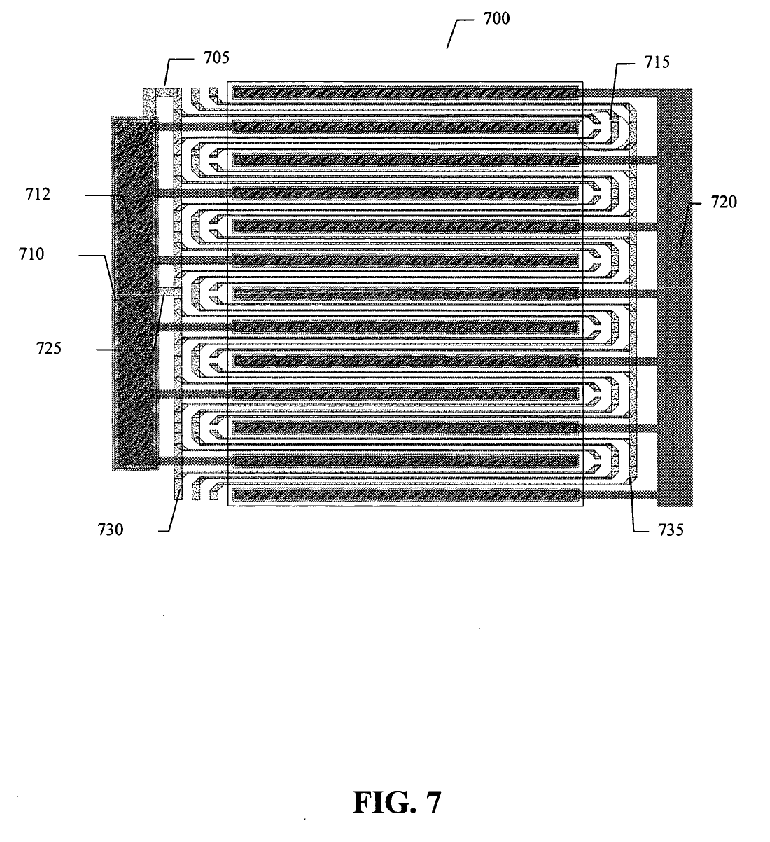

FIG. 7, generally at 700, illustrates an embodiment of the present invention which uses at least one gate rail 730 and 735 and odd symmetric feed 705 and 725 of a feed forward capacitor 712. In this embodiment, the odd asymmetrical coupling 705 and 725 of the at least one feedforward capacitor 712 with the FET is via the at least one gate rail 730 and 735 and is accomplished by a plurality of connecting points between the at least one gate rail 730 and 735 and the FET. It is understood that although two connecting points are illustrated herein any number of connecting points may be used and they may be placed in an infinite number of positions along the at least one gate rail 730 and 735. In this embodiment, the feedforward capacitor is integrated with source rail 710 or drain rail 720, although it is understood that in this embodiment as well as all embodiments, discreet feed forward capacitors may be used and be within the scope of the present inventions. Also, in this embodiment, the ends of gates 715 are shown as open, however, it is understood that the ends can be closed in this embodiment and all of the aforemention and following embodiments.

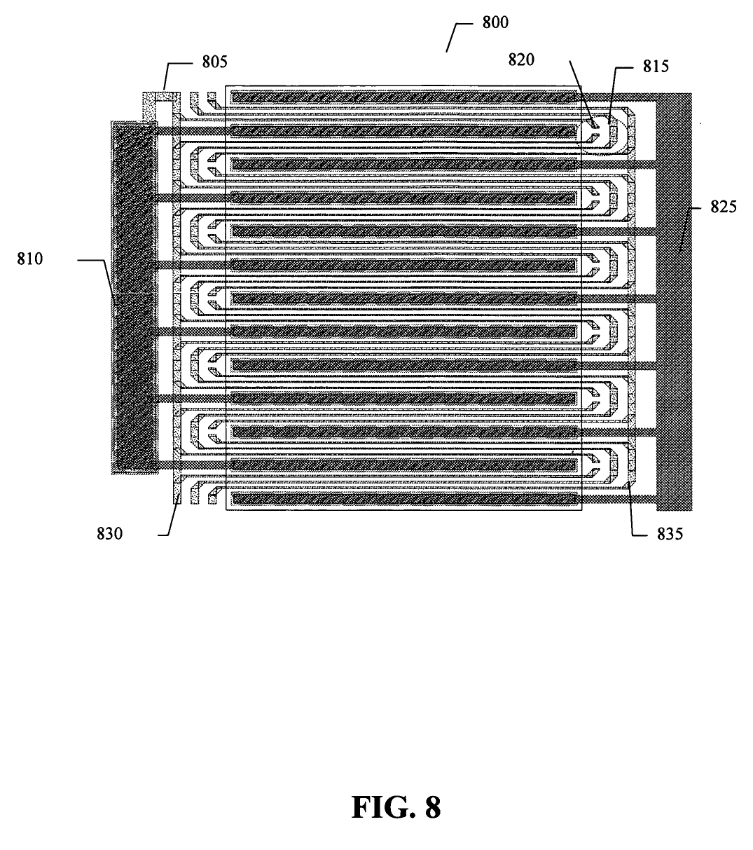

The embodiment of FIG. 8 at 800 reiterates the ability of the present invention to provide for open ends 820 of gates 815 while maintaining the structure of asymmetric coupling 805 using gate rails 830 and 835 integrated feed forward capacitor 810 and drain rail 825. This open end structure may greatly improve ease of manufacture.

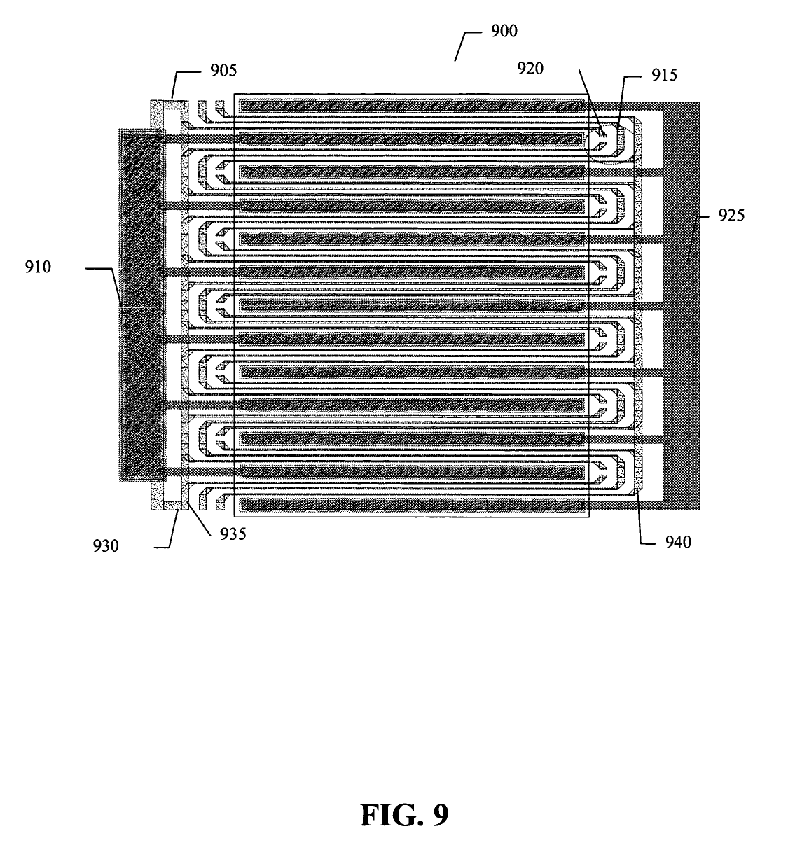

FIG. 9, shown generally at 900, illustrates an embodiment of the present invention which uses at least one gate rail 935 and 940 and even symmetric feed 905 and 930 of a feedforward capacitor 912 integrated with source rail 910. The embodiment of FIG. 9 also may utilize open ends 920 of gate 915. Drain rail is depicted in FIG. 9 at 925.

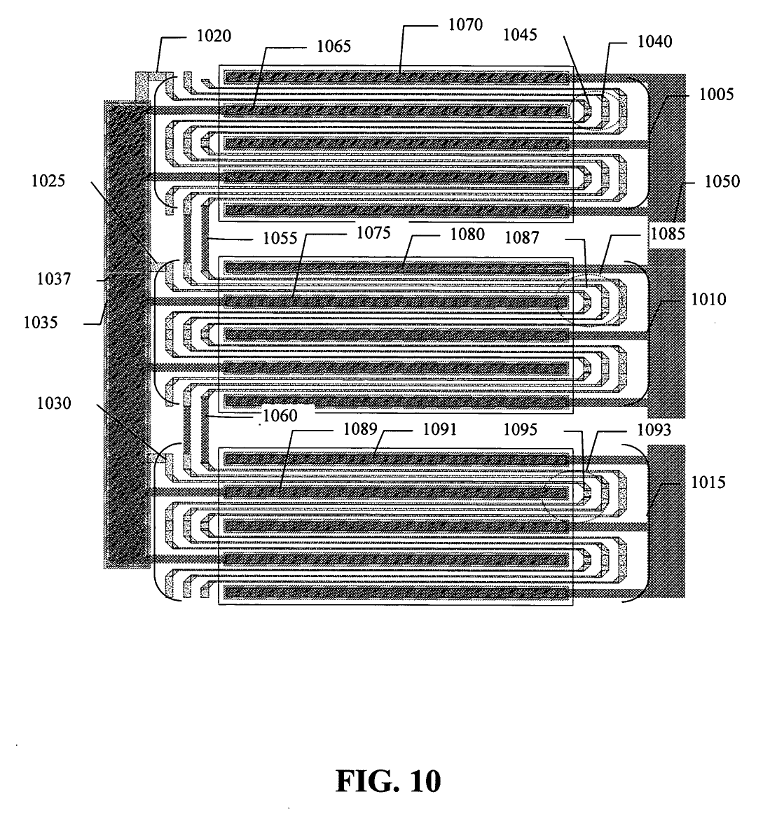

Turning now to FIG. 10 is provided at 1000 an illustration of an embodiment of the present invention which uses an array of parallel connected FETs 1005, 1010 and 1015 and asymmetrical feeding 1020 of feedforward capacitors 1037. The structure comprises a first field effect transistor (FET) 1005 comprising: at least one gate 1040 having a plurality of gate fingers 1045; at least one source rail 1035 with at least one source finger 1065; and at least one drain rail 1050 with at least one drain finger 1070; and at least one feedforward capacitor 1037 asymmetrically coupled 1020 with the first FET 105. The structure of this embodiment of the present invention further comprises a second field effect transistor (FET) 1010 comprising at least one gate 1085 having a plurality of gate fingers 1087; at least one source rail 1035 with at least one source finger 1075; and at least one drain rail 1050 with at least one drain finger 1080; and the at least one feedforward capacitor 1037 asymmetrically, even symmetrically or odd symmetrically coupled 1025 with the second FET 1010, the second FET 1010 may be coupled to the first FET 1005.

The structure of the embodiment of FIG. 10 can further comprise at least one additional FET 1015, the at least one additional FET 1015 may comprise at least one gate 1093 having a plurality of gate fingers 1095; at least one source rail 1035 with at least one source finger 1089; and at least one drain rail 1050 with at least one drain finger 1091; and the at least one feedforward capacitor 1037 may be asymmetrically, even symmetrically or odd symmetrically coupled 1030 with the at least one additional FET 1015, the at least one additional FET 1015 may be coupled to the second FET 1010 and/or to the first FET 1005.

The ends of the gate fingers 1045, 1087, 1095 may be closed as depicted in FIG. 10 or they may be open as depicted in other embodiments. Although not shown in the embodiment of FIG. 10, the at least one feedforward capacitor may coupled to the first FET and/or the second FET and/or the at least one additional FET via at least one gate rail. As articulated above, the feedfoward capacitor, although integrated in the embodiment of FIG. 10 with source rail 1035, may be a discrete capacitor that is asymmetrically, even symmetrically or odd symmetrically coupled with the first FET, the second FET, and/or the at least one additional FET. Further, the coupling with the discreet capacitor may take place via at least one gate rail.

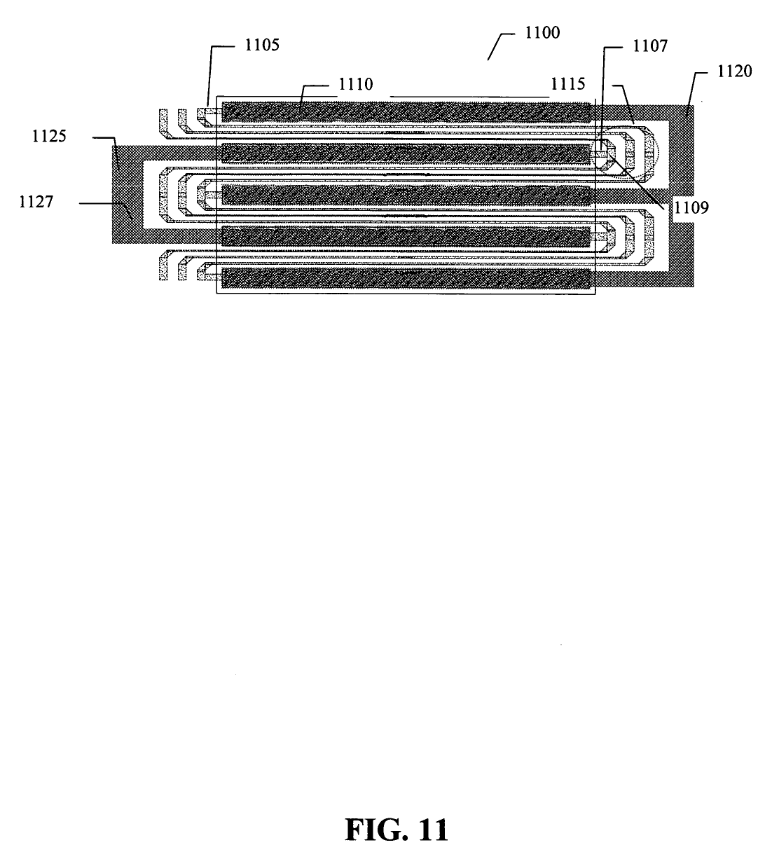

Turning now to FIG. 11, shown generally at 1100 is an embodiment of the present invention which uses distributed feedforward capacitors 1127 integrated 1105 and 1107 into a source 1125 and drain 1120 fingers. This embodiment may have closed ends 1109 of the fingers of gate 1115.

An embodiment of the present invention may further provide for a method of coupling RF energy into a gate network, comprising asymmetrically coupling a field effect transistor (FET) with a feedforward capacitor via a gate rail. The FET used in the present method may comprises: at least one gate having a plurality of gate fingers; at least one source rail having at least one source finger; and at least one drain rail having at least one drain finger. The method further provides serpentining between the at least one source finger and the at least one drain finger with at least one serpentine gate. Also, the present method may further comprise connecting the at least one feedforward capacitor via the at least one gate rail to the serpentine gate at first and second ends of the serpentine gate.

While the present invention has been described in terms of what are at present believed to be its preferred embodiments, those skilled in the art will recognize that various modifications to the disclose embodiments can be made without departing from the scope of the invention as defined by the following claims.

What is claimed is:

1. A structure comprising:
a field effect transistor (FET) comprising:
at least one source rail with at least one source finger;
at least one drain rail with at least one drain finger; and
at least one serpentine gate having a plurality of gate fingers, said serpentine gate serpentining between said at least one source finger and said at least one drain finger; and
at least one feedforward capacitor symmetrically coupled with said FET via at least one gate rail.

2. The structure of claim 1, wherein said serpentine gate includes first and second ends that are open at one end.

3. The structure of claim 1, wherein said serpentine gate includes first and second ends that are connected to said at least one gate rail.

4. The structure of claim 1, wherein said serpentine gate includes first and second ends that are connected to said at least one feedforward capacitor via said at least one gate rail.

5. A structure comprising:
a field effect transistor (FET) comprising:
at least one source rail with at least one source finger;
at least one drain rail with at least one drain finger; and
at least one serpentine gate having a plurality of gate fingers, said serpentine gate serpentining between said at least one source finger and said at least one drain finger; and
at least one feedforward capacitor odd symmetrically coupled with said FET via at least one gate rail.

6. The structure of claim 5, wherein said odd asymmetrical coupling of said at least one feedforward capacitor with said FET via said at least one gate rail is accomplished by a plurality of connecting points between said at least one gate rail and said FET.

7. The structure of claim 6, wherein said plurality of connecting points between said at least one gate rail and said FET occur at one extremity of said at least one gate rail and at least one interior portion of said at least one gate rail.

8. The structure of claim 5, wherein the ends of said at least one gate having a plurality of gate fingers is open.

9. The structure of claim 5, wherein the ends of said at least one gate having a plurality of gate fingers is open.

10. A structure comprising:
a first field effect transistor (FET) comprising:
at least one source rail with at least one source finger;
at least one drain rail with at least one drain finger; and
at least one serpentine gate having a plurality of gate fingers, said serpentine gate serpentining between said at least one source finger and said at least one drain finger; and
at least one feedforward capacitor asymmetrically coupled with said first FET;
a second field effect transistor (FET) comprising:
at least one source rail with at least one source finger;
at least one drain rail with at least one drain finger; and
at least one serpentine gate having a plurality of gate fingers, said serpentine gate serpentining between said at least one source finger and said at least one drain finger; and
said at least one feedforward capacitor asymmetrically, even symmetrically or odd symmetrically coupled with said second FET, said second FET coupled to said first FET.

11. The structure of claim 10, further comprising at least one additional FET, said at least one additional FET comprising:
at least one source rail with at least one source finger;
at least one drain rail with at least one drain finger; and
at least one serpentine gate having a plurality of gate fingers, said serpentine gate serpentining between said at least one source finger and said at least one drain finger; and
said at least one feedforward capacitor asymmetrically, even symmetrically or odd symmetrically coupled with said at least one additional FET, said at least one additional FET coupled to said second FET and/or to said first FET.

12. The structure of claim 11, wherein said at least one feedforward capacitor is coupled to said first FET and/or said second FET and/or said at least one additional FET via at least one gate rail.

13. A structure comprising:
a first field effect transistor (FET) comprising:
at least one gate having a plurality of gate fingers;
at least one source rail with at least one source finger; and
at least one drain rail with at least one drain finger; and
at least one discrete capacitor asymmetrically, even symmetrically or odd symmetrically coupled with said first FET;
a second field effect transistor (FET) comprising:
at least one gate having a plurality of gate fingers;
at least one source rail with at least one source finger; and
at least one drain rail with at least one drain finger; and
said at least one discrete capacitor asymmetrically, even symmetrically or odd symmetrically, coupled with said second FET, said second FET coupled to said first FET.

14. The structure of claim 13, further comprising at least one additional FET, said at least one additional FET comprising:
at least one gate having a plurality of gate fingers;
at least one source rail with at least one source finger; and
at least one drain rail with at least one drain finger; and
said at least one discrete capacitor asymmetrically, even symmetrically or odd symmetrically coupled with said at least one additional FET, said at least one additional FET coupled to said second FET and/or to said first FET.

15. The structure of claim 14, wherein said at least one discrete capacitor is coupled to said first FET and/or said second FET and/or said at least one additional FET via at least one gate rail.

16. A method of coupling RF energy into a gate network, comprising:
asymmetrically coupling a field effect transistor (FET) with a feedforward capacitor via a gate rail.

17. The method of claim 16, wherein said FET comprises:
at least one gate having a plurality of gate fingers;
at least one source rail with at least one source finger; and
at least one drain rail with at least one drain finger.

18. The method of claim 16, further comprising serpentining between said at least one source finger and said at least one drain finger with at least one serpentine gate.

19. The method of claim 16, further comprising connecting said at least one feedforward capacitor via said at least one gate rail to said serpentine gate at first and second ends of said serpentine gate.
